(19) United States
(12) Patent Application Publication
(10) Pub. No.: US 2022/0123119 A1
(43) Pub. Date: Apr. 21, 2022

(54) NON-VOLATILE MEMORY

(71) Applicant: STMicroelectronics (Rousset) SAS, Rousset (FR)

(72) Inventors: Christian RIVERO, Rousset (FR); Philippe BOIVIN, Venelles (FR); Francois TAILLIET, Fuveau (FR); Roberto SIMOLA, Trets (FR)

(73) Assignee: STMicroelectronics (Rousset) SAS, Rousset (FR)

(21) Appl. No.: 17/504,198

(22) Filed: Oct. 18, 2021

(30) Foreign Application Priority Data
Oct. 19, 2020 (FR) 2010688

(51) Int. Cl. H01L 29/423; H01L 27/11524; H01L 29/788; H01L 21/28; H01L 29/66

(52) U.S. Cl. CPC H01L 29/42336; H01L 27/11524; H01L 29/66825; H01L 29/40114; H01L 29/7883

(57) ABSTRACT

A memory transistor for a non-volatile memory cell includes a source region and a drain region implanted in a semiconductor substrate. The source region is spaced from the drain region. A double gate region for the memory transistor extends at least partly in depth in the semiconductor substrate between the source region and the drain region and further extends beyond this source region and this drain region. The memory cell further includes a selection transistor having a gate region that partially extends over the double gate region for the memory transistor.

### PRIORITY CLAIM

This application claims the priority benefit of French Application for Patent No. 2010688, filed on Oct. 19, 2020, the content of which is hereby incorporated by reference in its entirety to the maximum extent allowable by law.

### TECHNICAL FIELD

Embodiments and implementations relate to non-volatile memories and, in particular, to electrically erasable and programmable non-volatile memories (also known as Electrically Erasable Programmable Read Only Memory (EEPROM memory)).

### BACKGROUND

EEPROM memories are memories frequently used in integrated circuits.

EEPROM memories comprise several circuit pairs, called memory cells, of a memory transistor and a selection transistor. Each circuit pair forms a memory cell.

Memory transistors are used to store information.

The selection transistors are used to select the memory transistor which will be used to read information stored by this memory transistor, or else store new information in this memory transistor, or else erase information stored in this memory transistor.

In particular, the selection transistor can be a MOS transistor including a drain region, a source region and a gate region.

The memory transistor can be a double gate MOS transistor. The memory transistor then includes a drain region and a source region formed in the semiconductor substrate. The source region is spaced from the drain region to provide a channel between these two regions. The distance between the drain region and the source region thus allows to define an effective channel length. The source region of the selection transistor coincides with the drain region of the memory transistor.

The memory transistor also comprises a double gate region comprising two gates insulated from each other and disposed on the semiconductor substrate between the drain region and the source region of this memory transistor, above the channel. These two gates are therefore disposed away from the gate region of the selection transistor.

In particular, the two insulated gates are a floating gate and a control gate superimposed on the floating gate. A dielectric layer is interposed between the floating gate and the control gate to insulate the floating gate and the control gate from each other.

Furthermore, the memory transistor also comprises an insulating layer interposed between the floating gate and the semiconductor substrate. This insulating layer includes at least one adapted insulating part, which is sufficiently thin, for example, to allow charge carriers to pass, by tunneling effect, between the underlying channel and the floating gate. This sufficiently poorly insulating part is called “tunnel insulator”, “tunnel oxide” or “tunnel window”.

Moreover, the memory transistor and the selection transistor also comprise dielectric spacing regions (“spacers”) formed on the semiconductor substrate around the gate of this memory transistor and of this storage selection transistor.

The memory transistor and the selection transistor therefore occupy a certain surface on the semiconductor substrate.

In order to reduce the dimensions of an EEPROM memory or to increase the number of memory cells of an EEPROM memory on the same surface, it is advantageous to reduce the occupied surface area of the memory transistor and of the selection transistor of each memory cell of the EEPROM memory.

This reduction in the occupied surface areas of the memory transistor and of the selection transistor of each memory cell can be made possible by reducing the dimensions of these transistors.

Nevertheless, some physical and structural constraints may impose a minimum size for these transistors. This minimum size is necessary to ensure proper operation of these transistors.

In particular, reducing the dimensions of a memory transistor can lead to a decrease in the effective channel length of that memory transistor.

However, the reduction in the effective channel length of a memory transistor is limited by the appearance of hot carriers in the channel between the source region and the drain region of this transistor when the distance between these two regions is too short.

This appearance of hot carriers can hinder the proper operation of the memory transistor, in particular by modifying the value stored in the memory transistor.

Moreover, the space occupied by a circuit pair of a selection transistor and a memory transistor is conditioned by the use of dielectric spacing regions. It is therefore necessary to provide a space dedicated to these dielectric spacing regions.

There is therefore a need to provide transistors for a non-volatile memory with a reduced occupied surface area.

### SUMMARY

According to one aspect, an integrated circuit comprises at least one memory transistor for a non-volatile memory. The memory transistor comprises: a source region and a drain region in and/or on a semiconductor substrate, the source region being spaced from the drain region; and a double gate region extending at least partly in depth in the semiconductor substrate between the source region and the drain region and beyond this source region and this drain region.

The double-gate region, by extending at least partly in depth in the semiconductor substrate, allows to obtain a channel bypassing this double-gate region in depth in the semiconductor substrate.

More particularly, this channel extends in the semiconductor substrate from the drain region of the transistor to the source region, bypassing the double gate region in depth. Therefore, the effective channel length is greater than the distance between the drain region and the source region.

It is thus possible to reduce the distance between the drain region and the source region while maintaining an effective channel length sufficient to reduce a risk of appearance of hot carriers which may hinder the proper operation of the memory transistor.

The proposed memory transistor can therefore have a reduced occupied surface area compared to that of a conventional memory transistor.

The double gate region may comprise a first portion disposed on the surface of the semiconductor substrate and a second portion extending into the semiconductor substrate.

In an advantageous embodiment, the double gate region comprises: a first insulating layer in contact with the semiconductor substrate and delimiting the double gate region in the semiconductor substrate; a floating gate superimposed on the first insulating layer; a second insulating layer superimposed on the floating gate; and a control gate superimposed on the second insulating layer.

The first insulating layer is therefore interposed between the semiconductor substrate and the floating gate. The first insulating layer therefore allows to insulate the floating gate from the semiconductor substrate.

Furthermore, the second insulating layer is interposed between the control gate and the floating gate. The first insulating layer therefore insulates the floating gate from the control gate.

Advantageously, the first insulating layer, the floating gate, the second insulating layer and the control gate extend in depth into the semiconductor substrate.

Furthermore, advantageously, the first insulating layer includes at least one adapted insulating part, which is for example sufficiently thin, to allow charge carriers to pass, by tunneling effect, between the drain region and the floating gate.

In an advantageous embodiment, the double gate region extends in depth into the semiconductor substrate over a distance comprised between 50 nm and 800 nm.

Such a length in depth allows to obtain a channel having an effective length which is large enough to reduce, or even eliminate, a risk of appearance of hot carriers.

Furthermore, the volatile memory can comprise shallow insulation trenches between the memory cells. The aforementioned depth distance for the double gate region is then small enough to avoid a risk that the shallow insulation trenches are insufficient to insulate the memory transistor of one memory cell from other memory cells.

In an advantageous embodiment, the double gate region has a width comprised between 50 nm and 200 nm in the semiconductor substrate.

Advantageously, the integrated circuit comprises at least one memory cell for a non-volatile memory disposed on a semiconductor substrate and including: a selection transistor, and the memory transistor described above.

Advantageously, the source region of the selection transistor then coincides with the drain region of the memory transistor.

In one embodiment, the selection transistor has a gate region extending over the semiconductor substrate and being separated from the memory transistor by a dielectric spacing region. The selection transistor can then be a conventional MOS transistor.

Alternatively, in an advantageous embodiment, the selection transistor comprises a gate region extending on the surface of the semiconductor substrate partly on the double gate region of the memory transistor, the memory cell comprising an insulating layer interposed between the double gate region of the memory transistor and the gate region of the selection transistor.

In particular, the part of the gate region of the selection transistor extending over the double gate region of the memory transistor has the advantage of having a sufficiently large surface to receive a contact region configured to be able to apply a voltage to the gate region of the selection transistor.

The part of the gate region of the selection transistor extending over the semiconductor substrate can thus be reduced because it is not used to receive this contact region.

By reducing this last part of the selection transistor, it is possible to reduce the occupied surface area of the memory cell.

An integrated circuit comprising a volatile memory including at least one memory cell such as that described above is also proposed.

Although with such a memory cell the proposed selection transistor is combined with the proposed memory transistor, it is quite possible to provide a memory cell wherein the proposed selection transistor is combined with a conventional memory transistor.

Thus, according to another aspect, an integrated circuit comprising at least one memory cell is proposed for a non-volatile memory formed on a semiconductor substrate and comprising: a memory transistor having a double gate region extending only on the surface of the semiconductor substrate; and a selection transistor comprising a gate region extending on the surface of the semiconductor substrate partly over the double gate region of the memory transistor, the memory cell comprising an insulating layer interposed between the double gate region of the memory transistor and the gate region of the selection transistor.

According to another aspect, therefore an integrated circuit comprising a non-volatile memory including at least one such memory cell is also proposed.

This insulating layer allows to insulate the gate region of the selection transistor from the double gate region of the memory transistor.

The insulating layer interposed between the double gate region of the memory transistor and the gate region of the selection transistor allows to avoid the use of bulky dielectric spacing regions between the selection transistor and the memory transistor.

Indeed, as seen previously, the memory cells for EEPROM memory generally comprise a selection transistor disposed at a distance from a memory transistor, and spacing regions are used to insulate these transistors from each other. Such spacing regions occupy a large surface area on the semiconductor substrate.

Thus, the use of said insulating layer interposed between the double gate region of the memory transistor and the gate region of the selection transistor in the proposed memory cell allows to reduce the occupied surface area of this memory cell compared to the known memory cells.

Preferably, said insulating layer interposed between the double gate region of the memory transistor and the gate region of the selection transistor has a thickness comprised between 20 nm and 40 nm, for example of the order of 25 nm.

Preferably, this layer interposed between the double gate region of the memory transistor and the gate region of the selection transistor is an oxide layer.

Advantageously, the gate region of the selection transistor includes a first portion extending over the semiconductor substrate to the memory transistor, and a second portion which extends said first portion by partially covering the memory transistor.

In an advantageous embodiment, the first portion has a thickness comprised between 100 nm and 250 nm, for example of the order of 150 nm.

Preferably, the second portion includes a thickness comprised between 100 nm and 250 nm, for example of the order of 150 nm.

Furthermore, advantageously, the second portion of the gate region extends over the double gate region of the memory transistor over a length comprised between 20 nm and 50 nm, for example of the order of 25 nm.

According to another aspect, provision is made of a method for manufacturing a memory transistor for a non-volatile memory comprising: forming a source region and a drain region implanted in a semiconductor substrate, the source region being spaced from the drain region; and forming a double gate region extending in depth into the semiconductor substrate between the source region and the drain region and beyond the source region and the drain region.

In an advantageous implementation, the formation of the double gate region comprises: etching a trench in depth in the substrate and forming a first insulating layer on the walls of said trench; forming a floating gate on said first insulating layer; forming a second insulating layer on the floating gate; and forming a control gate on the second insulating layer.

According to another aspect, provision is made of a method for manufacturing a memory cell for a non-volatile memory on a semiconductor substrate comprising: manufacturing a memory transistor as described above; and manufacturing a selection transistor.

Advantageously, the manufacture of the memory transistor and the manufacture of the selection transistor are carried out so that the source region of the selection transistor coincides with the drain region of the memory transistor.

In one implementation, the selection transistor is manufactured so that it has a gate region extending over the semiconductor substrate and being separated from the memory transistor by a dielectric spacing region.

Alternatively, in an advantageous implementation, the selection transistor is manufactured so that it comprises a gate region extending on the surface of the semiconductor substrate partly on the double gate region of the memory transistor, an insulating layer being formed between the double gate region of the memory transistor and the gate region of the selection transistor.

As seen previously, although with such a memory cell the proposed selection transistor is combined with the proposed memory transistor, it is quite possible to provide a memory cell wherein the proposed selection transistor is combined with a conventional memory transistor.

Thus, according to another aspect, a method for manufacturing a memory cell on a semiconductor substrate comprises: forming a memory transistor having a double gate region extending only on the surface of the semiconductor substrate; forming a selection transistor comprising a gate region extending on the surface of the semiconductor substrate partly on the double gate region of the memory transistor; and forming an insulating layer between the double gate region of the memory transistor and the gate region of the selection transistor.

Preferably, said insulating layer interposed between the double gate region of the memory transistor and the gate region of the selection transistor has a thickness comprised between 20 nm and 40 nm, for example of the order of 25 nm.

Preferably, this layer interposed between the double gate region of the memory transistor and the gate region of the selection transistor is an oxide layer.

Advantageously, the gate region of the selection transistor includes a first portion extending over the semiconductor substrate to the memory transistor, and a second portion which extends said first portion by partially covering the memory transistor.

In an advantageous embodiment, the first portion has a thickness comprised between 100 nm and 250 nm, for example of the order of 150 nm.

Preferably, the second portion includes a thickness comprised between 100 nm and 250 nm, for example of the order of 150 nm.

Furthermore, advantageously, the second portion of the gate region extends over the double gate region of the memory transistor over a length comprised between 20 nm and 50 nm, for example of the order of 25 nm.

### BRIEF DESCRIPTION OF THE DRAWINGS

Other advantages and features of the invention will become apparent upon examining the detailed description of implementations and embodiments, which are in no way limiting, and the appended drawings wherein:

FIG. 1 illustrates a sectional view of a memory transistor TM for a non-volatile EEPROM memory;

FIG. 2 is a flow diagram for a method for manufacturing a memory transistor TM;

FIGS. 3-12 illustrate steps in the method of manufacturing;

FIG. 13 is a top view of the memory cell;

FIG. 14 is a sectional view of the memory cell shown in FIG. 13;

FIG. 15 illustrates a top view of a memory comprising several memory cells such as the one illustrated in FIGS. 13 and 14;

FIG. 16 is a top view of another embodiment of a memory cell;

FIG. 17 is a sectional view of the memory cell shown in FIG. 16;

FIG. 18 is a flow diagram for a method for manufacturing the memory cell of FIGS. 16-17;

FIGS. 19-21 illustrate steps in the method of manufacturing;

FIG. 22 illustrates a top view of a memory comprising several memory cells such as the one illustrated in FIGS. 16 and 17;

FIG. 23 is a sectional view of a memory cell having a memory transistor and a selection transistor;

FIG. 24 is a flow diagram for a method for manufacturing the memory cell of FIG. 23;

FIGS. 25-30 illustrate steps in the method of manufacturing; and

FIG. 31 illustrates a top view of a memory comprising several memory cells CM3 such as the one illustrated in FIG. 23.

### DETAILED DESCRIPTION

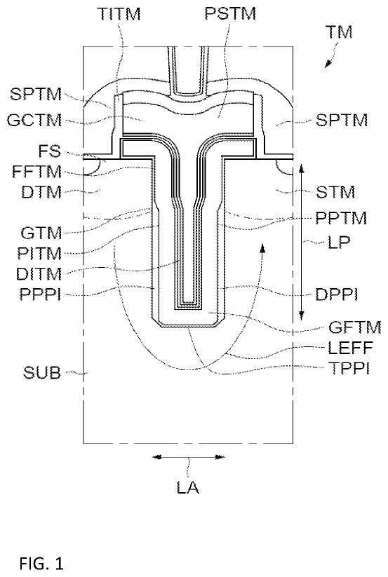

FIG. 1 illustrates a sectional view of a memory transistor TM for a non-volatile EEPROM memory according to one embodiment.

The memory transistor TM comprises a drain region DTM and a source region STM both formed in a semiconductor substrate SUB having a flat upper face FS.

The memory transistor TM also comprises a double gate region GTM. The double gate region GTM has a portion PPTM extending in depth into the semiconductor substrate SUB, between the drain region DTM and the source region STM, in a main direction orthogonal to said flat upper face FS.

The portion PPTM of the double gate region GTM extends in depth into the semiconductor substrate SUB over a distance LP comprised between 40 nm and 800 nm, for example of the order of 400 nm. Furthermore, this portion PPTM of the double gate region GTM has a width LA comprised between 50 nm and 200 nm, for example of the order of 80 nm.

The double gate region GTM comprises a floating gate GFTM and a control gate GCTM disposed between the drain DTM and the source STM region.

The double gate region GTM also comprises a first insulating layer PITM interposed between the floating gate GFTM and the semiconductor substrate SUB. This first insulating layer PITM allows the floating gate GFTM to be insulated from the semiconductor substrate SUB.

The double gate region GTM further comprises a second insulating layer DITM interposed between the floating gate GFTM and the control gate GCTM. This second insulating layer DITM allows to insulate the control gate GCTM from the floating gate GFTM.

The floating gate GFTM, the control gate GCTM, the first insulating layer PITM and the second insulating layer DITM are partly comprised in the portion PPTM, and therefore extend in depth into the semiconductor substrate SUB.

More particularly, the first insulating layer PITM is an oxide layer.

The first insulating layer PITM has a first lateral portion PPPI extending in depth into the semiconductor substrate SUB in said main direction from a proximal end at the upper face FS of the semiconductor substrate SUB against the drain region DTM up to a distal end deeper than the drain region DTM and the source region STM.

The first insulating layer PITM further has a second lateral portion DPPI extending in depth into the semiconductor substrate SUB in said main direction from a proximal end at the upper face FS of the semiconductor substrate SUB against the source region STM up to a distal end deeper than the drain region DTM and the source region STM. The distal end of this second portion DPPI of the first insulating layer PITM is at the same depth as the distal end of said first portion PPPI.

The first insulating layer PITM also has a third portion TPPI connecting the two distal ends of said first and second lateral portions PPPI, DPPI of the first insulating layer PITM.

The first insulating layer PITM includes on said first portion PPPI at least one part, called the tunnel window FTTM, which is sufficiently poorly insulating to allow charge carriers to pass, by the tunneling effect, between the drain region DTM and the floating gate GFTM.

In particular, this tunnel window FTTM of the first insulating layer has, for example, a thickness of less than 13 nm, for example comprised between 5 nm and 12 nm, in particular of the order of 8 nm.

The other parts of the first insulating layer PITM preferably have a thickness greater than 13 nm, for example comprised between 13 nm and 25 nm.

The floating gate GFTM is formed from a layer of polysilicon disposed on the first insulating layer PITM. The floating gate GFTM has a constant thickness as a whole.

The floating gate GFTM preferably has a thickness comprised between 1 nm and 25 nm, for example of the order of 5 nm.

The second insulating layer DITM extends over the entire floating gate GFTM.

The second insulating layer DITM preferably has a thickness greater than 10 nm, for example comprised between 10 nm and 25 nm, in particular of the order of 15 nm.

The second insulating layer DITM is a continuous layer of an oxide/nitride/oxide (ONO) superposition.

The control gate GCTM is formed over the entire second insulating layer DITM.

The control gate GCTM has a thickness comprised between 10 nm and 50 nm, for example of the order of 35 nm.

The control gate GCTM is formed of polysilicon.

The double gate region GTM of the memory transistor TM has a portion PSTM on the surface of the semiconductor substrate SUB, from which the portion PPTM extends in depth into the semiconductor substrate SUB.

This surface portion PSTM partly comprises the first insulating layer PITM, the floating gate GFTM, the second insulating layer DITM and the control gate GCTM.

The transistor TM further comprises a third insulating layer TITM covering said portion PSTM of the transistor on the surface of the semiconductor substrate.

The transistor can also comprise dielectric spacing regions SPTM (also designated by the term “spacers”) on the surface of the semiconductor substrate SUB, against the portion PSTM.

The depth portion PPTM of the double gate region GTM allows to obtain, in the semiconductor substrate, a channel connecting the drain region DTM to the source region STM by bypassing this depth portion PPTM of the double gate region GTM in depth.

Therefore, the effective channel length LEFF is greater than the distance between the drain region DTM and the source region STM.

It is thus possible to reduce the distance between the drain region DTM and the source region STM, to reduce the occupied surface area of the memory transistor compared to a conventional memory transistor while maintaining an effective channel length sufficient to reduce a risk of appearance of hot carriers which could hinder the correct operation of this memory transistor.

The memory transistor TM can therefore have a reduced occupied surface area compared to that of a conventional memory transistor.

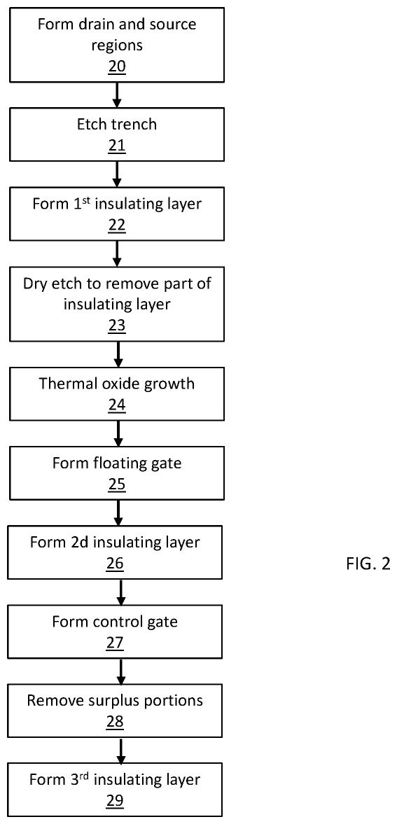

FIG. 2 illustrates steps of a method for manufacturing a memory transistor TM according to the embodiment described above.

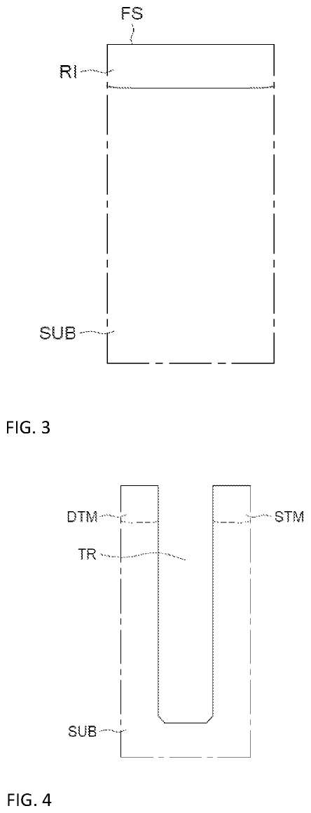

The method firstly comprises a step 20 of forming the drain region DTM and the source region STM of the memory transistor TM. In particular, this formation is carried out by implantation of ions in the same area of the semiconductor substrate SUB. This region of the substrate then comprises the drain region and the source region of the memory transistor. The drain region and the source region are then separated from each other by the depth portion PPTM of the double gate region GTM of the memory transistor, as will be detailed below. The result of this step 20 is illustrated in FIG. 3.

Then, the method comprises several steps to form the double gate region GTM of the transistor TM.

The method comprises an etching step 21 wherein a trench TR is formed in the semiconductor substrate SUB by dry etching, in particular of the reactive ionic etching type. This trench also allows to separate the drain region from the source region. The result of this step 21 is shown in FIG. 4.

The method further comprises a step 22 of forming an insulating layer COITM on the walls of the trench. This insulating layer is in particular an oxide layer. The formation of the oxide layer can be achieved by heating the semiconductor substrate SUB.

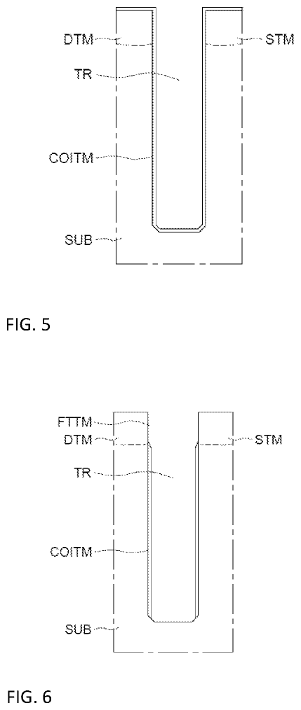

The result of this step 22 is shown in FIG. 5.

The method then comprises a step 23 of dry anisotropic etching. This dry etching allows to remove a portion of the oxide layer COITM in the trench TR at a proximal end of the trench TR at the upper face FS of the semiconductor substrate SUB. The result of this step 23 is shown in FIG. 6.

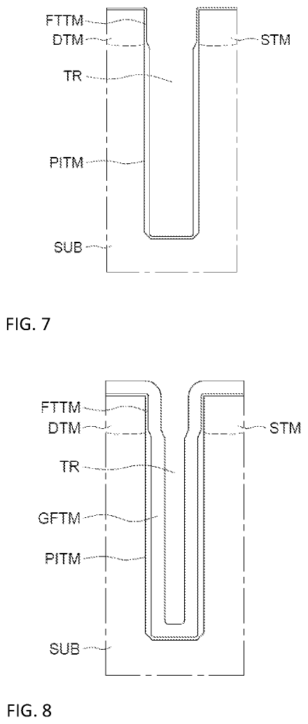

The method then comprises a heating step 24 during which the semiconductor substrate SUB is heated so as to grow the oxide in the trench. This step allows to obtain the first insulating layer PITM. The result of this step 24 is shown in FIG. 7.

In particular, heating the semiconductor substrate SUB once again allows to obtain an oxide layer, in the trench at the etched part, of a thickness less than the rest of the oxide layer COITM. This thinner part of the oxide layer allows to form said tunnel window FT of the first insulating layer PITM.

The method then comprises a step 25 of forming the floating gate GFTM. In this step, a continuous layer of polysilicon (polycrystalline silicon) forming said floating gate GFTM is deposited so as to cover the semiconductor substrate SUB, in particular in the trench TR on the first insulating layer PITM. As seen above, this layer has a thickness comprised between 13 nm and 25 nm. The result of this step 28 is shown in FIG. 8.

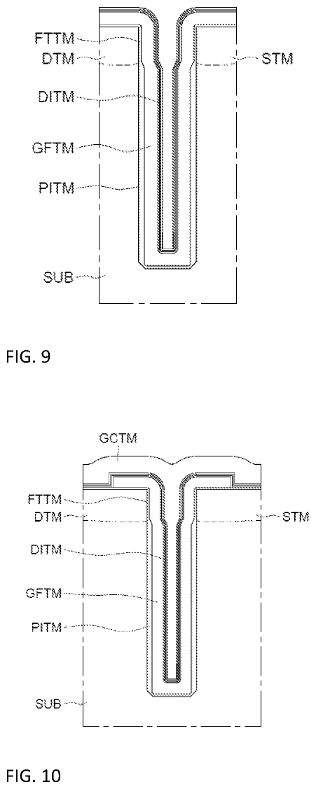

Then, the method comprises a step 26 of forming the second insulating layer DITM. In this step, a continuous oxide/nitride/oxide (ONO) layer, forming said second insulating layer, is deposited on the entire polysilicon layer forming the floating gate. As seen above, this layer has a thickness comprised between 10 nm and 25 nm. The result of this step 26 is shown in FIG. 9.

The method further comprises a step 27 of forming the control gate GCTM. In this step, a continuous layer of polysilicon forming the control gate GCTM is deposited on the second insulating layer DITM. As seen above, this layer has a thickness comprised between 10 nm and 50 nm. The result of this step is shown in FIG. 10.

Then, during a step 28, the surplus portions of the polysilicon layers forming the floating gate GFTM, of oxide/nitride/oxide and of polysilicon forming the control gate GCTM which extend beyond the memory transistor are eliminated.

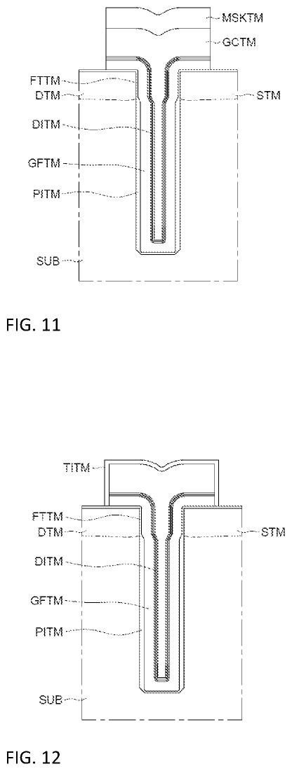

For this purpose, these portions are eliminated by etching. In order to protect the memory transistor during this elimination, a mask MSKTM formed from a resin is used which is deposited on the transistor. The resin can be a planarizing photosensitive resin. The manufacture of such a mask is well known to the person skilled in the art. The result of this step is shown in FIG. 11. The mask MSKTM is then removed.

Then, the method can comprise a step 29 of forming said third insulating layer TITM on the portion of the double gate region GTM on the surface of the semiconductor substrate SUB. The result of this step is shown in FIG. 12.

The method may also comprise a step of forming dielectric spacing regions.

The memory transistor TM is obtained at the end of this step.

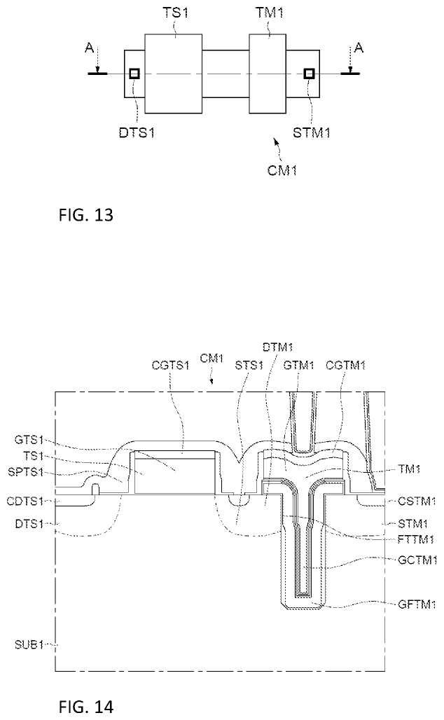

FIGS. 13 and 14 schematically illustrate a memory cell CM1 of an EEPROM memory according to one embodiment, formed on a semiconductor substrate SUB1. FIG. 13 is a top view of the memory cell CM1 and FIG. 14 is a sectional view of this memory cell CM1 along section A-A shown in FIG. 13.

The memory cell CM1 comprises a memory transistor TM1, identical to the transistor TM described above, as well as a conventional selection transistor TS1 well known to the person skilled in the art.

The selection transistor TS1 is a MOS transistor including a drain region DTS1, a source region STS1 and a gate region GTS1. The source region GTS1 of the selection transistor TS coincides with the drain region DTM1 of the memory transistor TM1.

The selection transistor TS1 also comprises a dielectric spacing region SPTS1 formed on the gate region GTS1.

The memory cell also comprises a first contact region CDTS1 on the drain region of the selection transistor.

The memory cell further comprises a second contact region CSTM1 formed on the source region STM1 of the memory transistor TM1.

The memory cell also comprises a third contact region CGTS1 formed on the gate region GTS1 of the selection transistor TS1.

The memory cell also comprises a fourth contact region CGTM1 formed on the control gate GCTM1 of the double gate region GTM1 of the memory transistor TM1.

The operation of the memory cell CM1 is as follows. An operation of erasing the memory cell is carried out by turning on the selection transistor TS1, by applying a voltage of 0 volts to the drain region DTM1 and to the source region STM1 of the memory transistor TM1, and by applying an erase potential to the control gate GCTM1 of this memory transistor TM1. This causes the passage of charges (for example electrons when the control gate is set to a positive erase potential) from the drain region DTM1 of the memory transistor TM1 to the floating gate GFTM1 of this memory transistor TM1 through the tunnel window FTTM1 and the accumulation of charges in the floating gate GFTM1.

A write operation in the memory cell CM1 is performed by turning on the selection transistor TS1, by applying a write voltage between the drain region DTM1 and the source region STM1 of the memory transistor TM1 and maintaining the gate control GCTM1 of this memory transistor at 0 volts. This causes the charges stored in the floating gate GFTM1 of the memory transistor TM1 to be evacuated through the tunnel window FTTM1.

A read operation is performed by turning on the selection transistor TS1, by applying a read voltage, lower than the write voltage, between the drain region DTM1 and the source region STM1 of the memory transistor TM1, and by setting the control gate GCTM1 of this memory transistor TM1 to a given read potential. The threshold voltage of the memory transistor TM1 is higher when charges are stored in the floating gate GFTM1 of this memory transistor TM1. The intensity of the current flowing through the memory transistor TM1 is then representative of the presence or absence of charges in the floating gate GFTM1 of the memory transistor TM1.

A method for manufacturing such a memory cell comprises manufacturing a memory transistor TM1 as described above for the transistor TM and manufacturing a MOS transistor well known to the person skilled in the art for the selection transistor TS1.

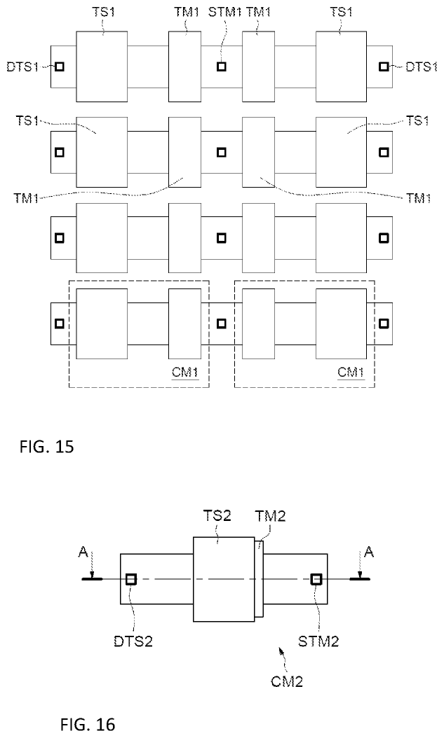

FIG. 15 illustrates a top view of a memory comprising several memory cells CM1 such as the one illustrated in FIGS. 13 and 14.

In particular, the memory cells CM1 are disposed in rows parallel to one another.

The memory transistors of the memory cells in the same row have their common control gate. The control gate extends so as to electrically connect the gate regions of each memory transistor in that row.

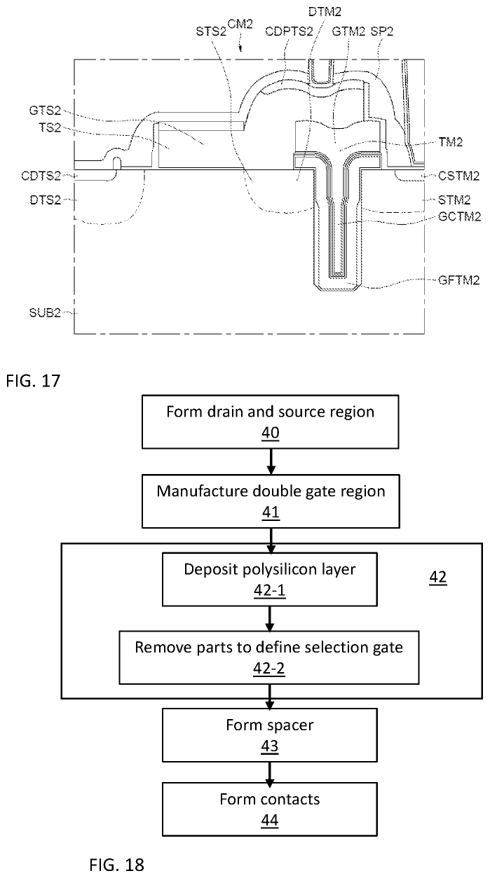

FIGS. 16 and 17 schematically illustrate another embodiment of a memory cell CM2 formed on a semiconductor substrate SUB2. FIG. 16 is a top view of the memory cell CM2 and FIG. 17 is a sectional view of this memory cell CM2 along section A-A shown in FIG. 16.

This memory cell CM2 comprises a memory transistor TM2 similar to the transistor TM described above and a selection transistor TS2 which differs from a conventional selection transistor such as the transistor TS1 described above.

This proposed selection transistor TS2 allows to reduce the area occupied by the memory cell CM2 on the semiconductor substrate compared to the memory cell CM1 described above.

In particular, the selection transistor TS2 comprises a drain region DTS2 and a source region STS2 formed in the semiconductor substrate SUB2.

The selection transistor TS2 further comprises a gate region GTS2 formed on the surface of the semiconductor substrate SUB2. The source region STS2 of the selection transistor TS2 coincides with the drain region DTM2 of the memory transistor TM2.

In particular, the gate region GTS2 includes a first portion PPTS2 extending over the semiconductor substrate SUB2 to the memory transistor TM2, in particular to the surface portion PSTM2 of the double gate region GTM2 of the memory transistor TM2. The first portion PPTS2 has a thickness comprised between 100 nm and 250 nm, for example of the order of 150 nm.

The gate region GTS2 also includes a second portion DPTS2 which extends said first portion PPTS2 by partially covering the double gate region GTM2 of the memory transistor TM2. The second portion DPTS2 includes a thickness comprised between 100 nm and 250 nm, for example of the order of 150 nm. Furthermore, this second portion DPTS2 of the gate region GTS2 extends over the double gate region GTM2 over a length comprised between 20 nm and 50 nm, for example of the order of 25 nm.

The first portion PPTS2 and the second portion DPTS2 are therefore formed in one piece.

In particular, the gate region GTS2 is formed from a layer of polysilicon.

The gate region GTS2 of the selection transistor TS2 is insulated from the double gate region GTM2 of the memory transistor TM2 by an insulating layer ISO2. This insulating layer ISO2 is interposed between the polysilicon layer of the gate region GTS2 of the selection transistor TS2 and the surface portion of the double gate region GTM2 of the memory transistor TM2.

Preferably, this layer ISO2 has a thickness comprised between 15 nm and 30 nm, for example of the order of 25 nm.

Preferably, this layer ISO2 is an oxide layer.

This insulating layer ISO2 allows to avoid the use of bulky dielectric spacing regions between the selection transistor and the memory transistor.

The memory cell CM2 also comprises a dielectric spacing layer SP2 (“spacer”) formed on the selection transistor TS2 and the memory transistor TM2.

The memory cell CM2 also comprises a first contact region CDTS2 on the drain region DTS2 of the selection transistor TS2.

The memory cell CM2 further comprises a second contact region CSTM2 formed on the source region STM2 of the memory transistor TM2.

The memory cell CM2 also comprises a third contact region CDPTS2 formed on the second portion DPTS2 of the selection transistor TS2. In particular, the second portion DPTS2 has the advantage of having a surface which is large enough to receive the third contact region CDPTS2. The first portion PPTS2 can thus be reduced because it is not used to receive said third contact region. By reducing the first portion PPTS2 of the selection transistor, it is possible to reduce the area occupied by the memory cell CM2.

The memory cell CM2 also comprises a fourth contact region (not shown) formed on the control gate GCTM2 of the memory transistor TM2, on an area above the control gate which is not covered by the selection transistor TS2.

The operation of the memory cell CM2 is similar to that of the memory cell CM1 described above.

In particular, an operation of erasing the memory cell is carried out by turning on the selection transistor TS2, by applying a voltage of 0 volts to the drain region DTM2 and to the source region STM2 of the memory transistor TM2, and by applying an erase potential to the control gate GCTM2 of this memory transistor TM2. This causes the passage of charges (for example electrons when the control gate is set to a positive erase potential) from the drain region DTM2 of the memory transistor TM2 to the floating gate GFTM2 of this memory transistor TM2 through the tunnel window FTTM2 and the accumulation of charges in the floating gate GFTM2.

A write operation in the memory cell CM2 is performed by turning on the selection transistor TS2, by applying a write voltage between the drain region DTM2 and the source region STM2 of the memory transistor TM2 and maintaining the gate control GCTM2 of this memory transistor at 0 volts. This causes the charges stored in the floating gate GFTM2 of the memory transistor TM2 to be evacuated through the tunnel window FTTM2.

A read operation is performed by turning on the selection transistor TS2, by applying a read voltage, lower than the write voltage, between the drain region DTM2 and the source region STM2 of the memory transistor TM2, and by setting the control gate GCTM2 of this memory transistor TM2 to a given read potential. The threshold voltage of the memory transistor TM2 is higher when charges are stored in the floating gate GFTM2 of this memory transistor TM2. The intensity of the current flowing through the memory transistor TM2 is then representative of the presence or absence of charges in the floating gate GFTM2 of the memory transistor TM2.

A method for manufacturing the memory cell CM2 shown in FIGS. 16 and 17 is illustrated in FIG. 18.

The method firstly comprises a step 40 of forming the source STS2 and drain DTS2 regions of the selection transistor TS2 and the source STM2 and drain DTM2 regions of the memory transistor TM2.

This formation 40 is carried out by implanting ions in two areas of the semiconductor substrate SUB2. A first area constitutes the drain region GTS2 of the selection transistor TS2. The second area is used to constitute the source STM2 and drain DTM2 regions of the memory transistor TM2 and the source region STS2 of the selection transistor TS2.

The method then comprises a step 41 of manufacturing the double gate region GTM2 of the memory transistor TM2 as described above and illustrated in FIGS. 4 to 11. This manufacture comprises in particular the manufacture of the floating gate GFTM2 and the control gate GCTM2.

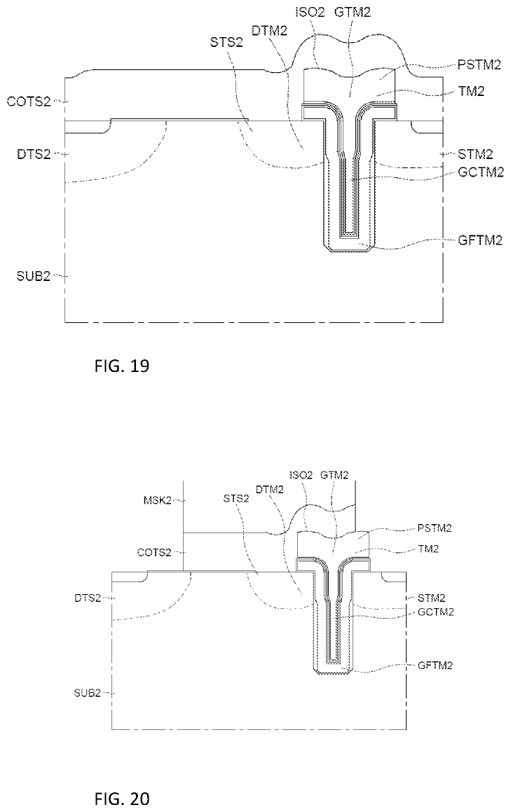

The method then comprises a step 42 of manufacturing the gate region GTS2 of the selection transistor TS2. The manufacture of the gate region GTS2 of the selection transistor TS2 comprises the deposition 42-1 of a polysilicon layer COTS2 on the entire memory cell CM2. The layer therefore extends over the semiconductor substrate SUB2 and over the memory transistor TM2. The result of this step is shown in FIG. 19.

The manufacture of the gate region GTS2 then comprises a removal 42-2 of the parts of the previously deposited polysilicon layer COTS2 which are not used to form the gate region GTS2 of the selection transistor TS2. In order to remove these different parts, a mask MSK2 is deposited beforehand on the part of the polysilicon layer COTS2 used to form the gate region GTS2 of the selection transistor TS2. The result of this removal is shown in FIG. 20. The mask MSK2 is then removed.

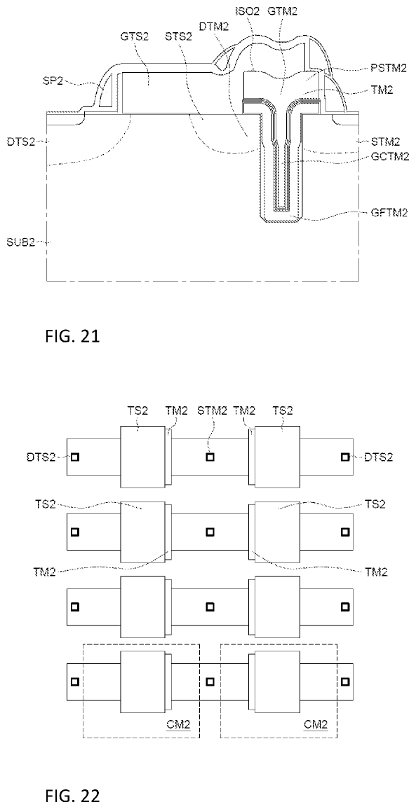

The method then comprises a step 43 of forming the dielectric spacing layer SP2 on the selection transistor TS2 and the memory transistor TM2. The result of this step 43 is illustrated in FIG. 21.

The method further comprises a step 44 of forming the contact regions CDTS2 and CGTS2 on the drain region DTS2 and on the gate region GTS2 of the selection transistor TS2 as well as a contact region CSTM2 on the source region and a contact region (not shown) on the double gate region GTM2 of the memory transistor TM2. In particular, the contact region formed on the double gate region GTM2 of the memory transistor TM2 can be produced on an area above the control gate which is not covered by the selection transistor TS2.

FIG. 22 illustrates a top view of a memory MEM2 comprising several memory cells CM2 such as the one illustrated in FIGS. 16 and 17.

In particular, the memory cells CM2 are disposed in rows parallel to one another.

The memory transistors TM2 of the memory cells CM2 in the same row have their common control gate. The control gate GCTM2 extends so as to electrically connect the double gate regions GCTM2 of each memory transistor TM2 in that row.

Although in the memory cell CM2 shown in FIGS. 16 and 17, the proposed selection transistor TS2 is combined with the proposed memory transistor TM2, it is quite possible to provide a memory cell wherein the proposed selection transistor is combined with a conventional memory transistor.

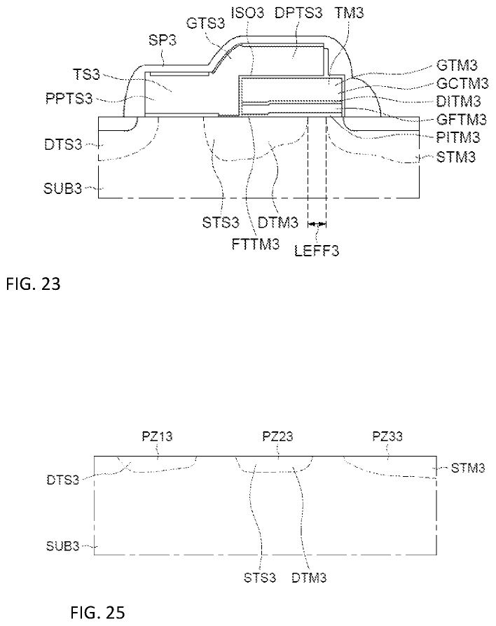

As such, FIG. 23 illustrates a sectional view of a memory cell CM3 having a conventional memory transistor TM3 and a selection transistor TS3 as proposed, formed in a semiconductor substrate SUB3.

The memory transistor TM3 includes a drain region DTM3 and a source region STM3 formed in the semiconductor substrate SUB3 and a double gate region GTM3 formed on the semiconductor substrate SUB3 between the drain region and the source region. A channel of length LEFF3 is thus formed between the drain region DTM3 and the source region STM3.

The double gate region GTM3 of the memory transistor TM3 comprises a floating gate GFTM3 and a control gate GCTM3.

The double gate region GTM3 of the memory transistor TM3 further comprises a first insulating layer PITM3 formed on the semiconductor substrate SUB3, between the semiconductor substrate SUB3 and the floating gate GFTM3. This first insulating layer PITM3 includes at least one part, called the tunnel window FTTM3, which is sufficiently poorly insulating to allow charge carriers to pass, by the tunneling effect, between the drain region DTM3 and the floating gate GFTM3.

The double gate region GTM3 further comprises a second insulating layer DITM3 between the floating gate GFTM3 and the control gate GCTM3.

Moreover, the selection transistor TS3 comprises a drain region DTS3 and a source region STS3 formed in the semiconductor substrate SUB3.

The selection transistor TS3 further comprises a gate region GTS3 formed on the surface of the semiconductor substrate SUB3. The source region STS3 of the selection transistor TS3 coincides with the drain region DTM3 of the memory transistor TM3.

In particular, the gate region GTS3 of the selection transistor TS3 includes a first portion PPTS3 extending over the semiconductor substrate SUB3 to the memory transistor TM3. The first portion PPTS3 has a thickness comprised between 100 nm and 250 nm, for example of the order of 150 nm.

The gate region GTS3 also includes a second portion DPTS3 which extends said first portion PPTS3 by partially covering the memory transistor TM3. The second portion DPTS3 includes a thickness comprised between 100 nm and 250 nm, for example of the order of 150 nm. Furthermore, this second portion DPTS3 of the gate region GTS3 extends over the double gate region GTM3 over a length comprised between 20 nm and 50 nm, for example of the order of 25 nm.

The first portion PPTS3 and the second portion DPTS3 are therefore formed in one piece.

In particular, the gate region GTS3 of the selection transducer TS3 is formed from a layer of polysilicon.

The memory cell CM3 comprises an insulating layer ISO3 interposed between the gate region GTS3 of the selection transistor TS3 and the double gate region GTM3 of the memory transistor TM3. This insulating layer ISO3 allows to insulate the gate region GTS3 of the selection transistor TS3 from the double gate region GTM3 of the memory transistor TM3.

Preferably, this layer ISO3 has a thickness comprised between 15 nm and 30 nm, for example of the order of 25 nm.

Preferably, this layer ISO3 is an oxide layer.

This insulating layer ISO3 allows to avoid the use of bulky dielectric spacing regions between the selection transistor and the memory transistor.

The memory cell CM3 also comprises a dielectric spacing layer SP3 (“spacer”) formed on the selection transistor TS3 and the memory transistor TM3.

The memory cell CM3 also comprises a first contact region CDTS3 on the drain region DTS3 of the selection transistor TS3.

The memory cell CM3 further comprises a second contact region CSTM3 formed on the source region STM3 of the memory transistor TM3.

The memory cell CM3 also comprises a third contact region GCTS3 formed on the second portion of the gate region GTS3 of the selection transistor TS3.

The memory cell CM3 also comprises a fourth contact region (not shown) formed on the control gate of the memory transistor TM3, on an area above the control gate which is not covered by the selection transistor TS3.

The operation of the memory cell CM3 is similar to that of the memory cell CM2 described above.

In particular, an operation of erasing the memory cell is carried out by turning on the selection transistor TS3, by applying a voltage of 0 volts to the drain region DTM3 and to the source region STM3 of the memory transistor TM3, and by applying an erase potential to the control gate GCTM3 of this memory transistor TM3. This causes the passage of charges (for example electrons when the control gate is set to a positive erase potential) from the drain region DTM3 of the memory transistor TM3 to the floating gate GFTM3 of this memory transistor TM3 through the tunnel window FTTM3 and the accumulation of charges in the floating gate GFTM3.

A write operation in the memory cell CM3 is performed by turning on the selection transistor TS3, by applying a write voltage between the drain region DTM3 and the source region STM3 of the memory transistor TM3 and maintaining the gate control GCTM3 of this memory transistor at 0 volts. This causes the charges stored in the floating gate GFTM3 of the memory transistor TM3 to be evacuated through the tunnel window FTTM3.

A read operation is performed by turning on the selection transistor TS3, by applying a read voltage, lower than the write voltage, between the drain region DTM3 and the source region STM3 of the memory transistor TM3, and by setting the control gate GCTM3 of this memory transistor TM3 to a given read potential. The threshold voltage of the memory transistor TM3 is higher when charges are stored in the floating gate GFTM3 of this memory transistor TM3. The intensity of the current flowing through the memory transistor TM3 is then representative of the presence or absence of charges in the floating gate GFTM3 of the memory transistor TM3.

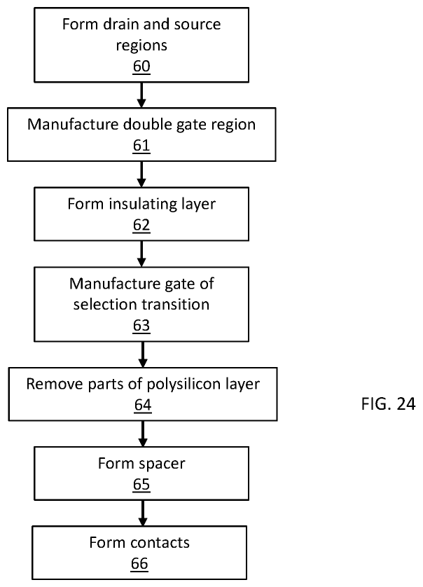

A method for manufacturing the memory cell CM3 shown in FIG. 23 is illustrated in FIG. 24.

The method firstly comprises a step 60 of forming the source STS3 and drain DTS3 regions of the selection transistor TS3 and the source STM3 and drain DTM3 regions of the memory transistor TM3.

This formation is carried out by implanting ions in three areas PZ13, PZ23, PZ33 of the semiconductor substrate SUB3. A first area PZ13 constitutes the drain region DTS3 of the selection transistor TS3. The second area PZ23 is used to constitute the drain region DTM3 of the memory transistor TM3 and the source region STS3 of the selection transistor TS3. The third area PZ33 is used to constitute the source region STM3 of the memory transistor. The second area PZ23 is thus located between the first area PZ13 and the third area PZ33. The result of this step 60 is shown in FIG. 25.

The method then comprises a step 61 of manufacturing the double gate region GTM3 of the memory transistor TM3. This double gate region GTM3 of the memory transistor TM3 is manufactured in a conventional manner.

In particular, the manufacture of the double gate region GTM3 comprises forming said first insulating layer PITM3 on the semiconductor substrate SUB3 between the drain region DTM3 and the source region STM3. This first insulating layer PITM3 is formed so that it includes said tunnel window FTTM3.

The manufacture of the double gate region GTM3 then comprises forming the floating gate GFTM3 on the first insulating layer PITM3.

The manufacture of the double gate region GTM3 then comprises forming said second insulating layer DITM3 on the floating gate GFTM3.

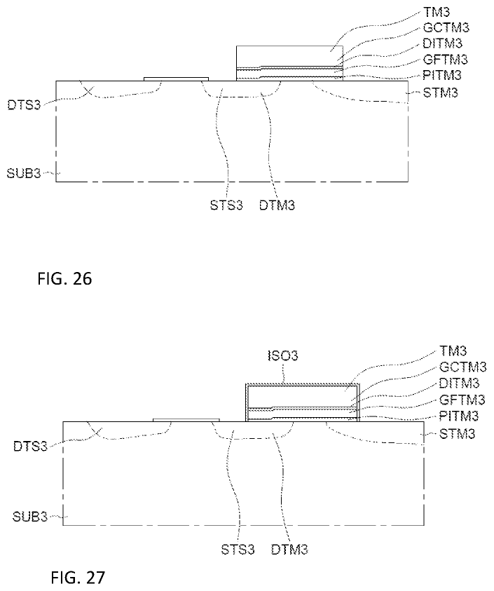

The manufacture of the double gate region GTM3 then comprises forming the control gate GCTM3 on the second insulating layer DITM3, so as to obtain the double gate region GTM3. The result of this step 61 is shown in FIG. 26.

The method then comprises a step 62 of forming said insulating layer ISO3 on the double gate region GTM3 of the memory transistor TM3. The result of this step 62 is shown in FIG. 27.

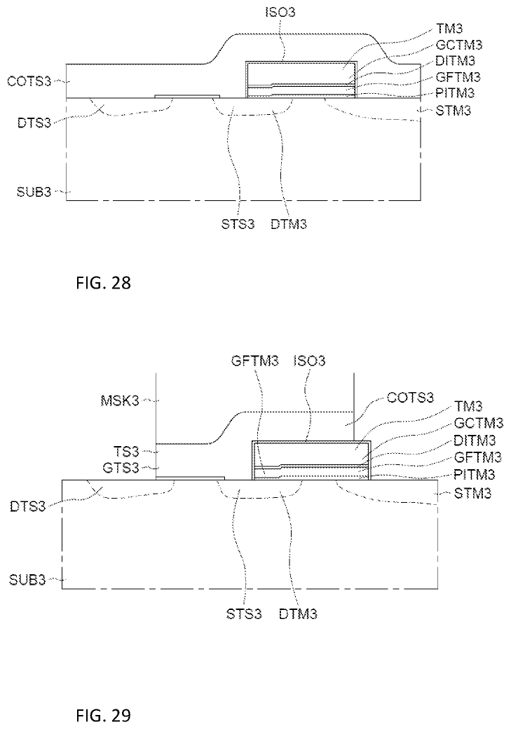

The method then comprises a step 63 of manufacturing the gate region GTS3 of the selection transistor TS3. The manufacture of the gate region GTS3 of the selection transistor TS3 comprises the deposition of a polysilicon layer COTS3 over the entire memory cell CM3. The layer COTS3 therefore extends over the semiconductor substrate SUB3 and over the memory transistor TM3, in particular over the insulating layer ISO3. The result of this step 63 is shown in FIG. 28.

The manufacture of the gate region GTS3 of the selection transistor TS3 then comprises a step 64 of removing the parts of the previously deposited polysilicon layer OTS3 which are not used to form the gate region GTS3 of the selection transistor TS3. In order to remove these different parts, a mask MSK3 is deposited beforehand on the part of the polysilicon layer COTS3 used to form the gate region GTS3 of the selection transistor TS3. The result of this removal is shown in FIG. 29. The mask MSK3 is then removed.

The method then comprises a step 65 of forming the dielectric spacing layer SP3 on the selection transistor TS3 and the memory transistor TM3.

The method further comprises a step 66 of forming contact regions CDTS3, CGTS3 on the drain region and on the gate region of the selection transistor TS3 as well as a contact region CSTM3 on the source region and a contact region (not shown) on the double gate region of the memory transistor. In particular, the contact region formed on the double gate region of the memory transistor TM3 can be produced on an area above the control gate GCTM3 which is not covered by the selection transistor TS3.

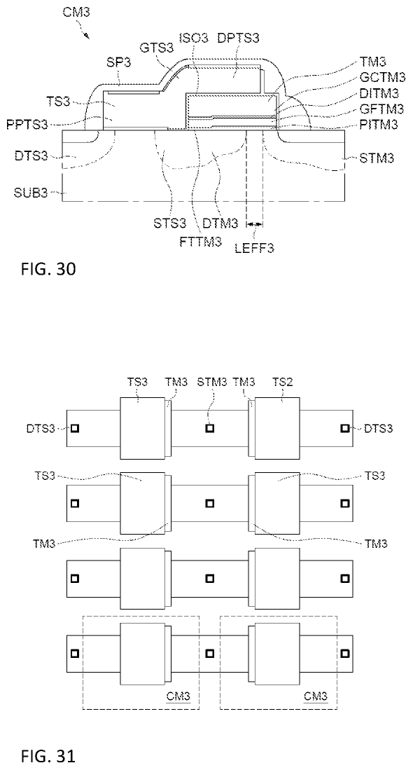

The result of steps 65 and 66 is shown in FIG. 30.

The memory cell CM3 is then obtained.

FIG. 31 illustrates a top view of a memory MEM3 comprising several memory cells CM3 such as the one illustrated in FIG. 23.

In particular, the memory cells CM3 are disposed in rows parallel to one another.

The memory transistors TM3 of the memory cells CM3 in the same row have their common control gate GCTM3. The control gate GCTM3 extends so as to electrically connect the gate regions GTM3 of each memory transistor TM3 in that row.

1. An integrated circuit including a non-volatile memory cell, comprising a selection transistor and a memory transistor supported by a semiconductor substrate;
wherein the memory transistor comprises a double gate region extending at least partly in depth into the semiconductor substrate from an upper surface of the semiconductor substrate;
wherein the selection transistor comprises a selection gate region including a first part that extends over the upper surface of the semiconductor substrate and a second part that extends over the double gate region of the memory transistor;
wherein the memory cell further comprises an insulating layer interposed between the double gate region of the memory transistor and the selection gate region of the selection transistor.

2. The integrated circuit according to claim 1, wherein the memory transistor further comprises:
a source region and a drain region supported by the semiconductor substrate, wherein the source region is spaced from the drain region by a trench region; and
wherein said double gate region is formed at least partly in said trench region between the source region and the drain region.

3. The integrated circuit according to claim 2, wherein a depth of the trench region is deeper than a depth of the source region and the drain region.

4. The integrated circuit according to claim 2, wherein the double gate region comprises:
a first insulating layer in contact with the semiconductor substrate in said trench region and delimiting the double gate region in the semiconductor substrate;
a floating gate superimposed on the first insulating layer;
a second insulating layer superimposed on the floating gate; and
a control gate superimposed on the second insulating layer.

5. The integrated circuit according to claim 4, wherein the first insulating layer, the floating gate, the second insulating layer and the control gate are positioned on side walls and a bottom of the trench region.

6. The integrated circuit according to claim 5, wherein the first insulating layer includes at least one insulating part that is configured to allow charge carriers to pass, by tunneling effect, between the drain region and the floating gate.

7. The integrated circuit according to claim 2, wherein a depth of the trench region is between 50 nm and 800 nm.

8. The integrated circuit according to claim 2, wherein the double gate region has a width comprised between 50 nm and 200 nm in the trench region.

9. The integrated circuit according to claim 2, wherein the selection transistor comprises a source region and a drain region supported by the semiconductor substrate, wherein the source region of the selection transistor is shared with the drain region of the memory transistor.

10. An integrated circuit including a non-volatile memory cell, comprising a selection transistor and a memory transistor supported by a semiconductor substrate;
wherein the memory transistor comprises a double gate region extending over and insulated from an upper surface of the semiconductor substrate;
wherein the selection transistor comprises a selection gate region including a first part that extends over the upper surface of the semiconductor substrate and a second part that extends over the double gate region of the memory transistor;
wherein the memory cell further comprises an insulating layer interposed between the double gate region of the memory transistor and the selection gate region of the selection transistor.

11. The integrated circuit according to claim 10, wherein the memory transistor further comprises a source region and a drain region supported by the semiconductor substrate.

12. The integrated circuit according to claim 11, wherein the double gate region comprises:
a first insulating layer in contact with the semiconductor substrate;
a floating gate superimposed on the first insulating layer;
a second insulating layer superimposed on the floating gate; and
a control gate superimposed on the second insulating layer.

13. The integrated circuit according to claim 12, wherein the first insulating layer includes at least one insulating part that is configured to allow charge carriers to pass, by tunneling effect, between the drain region and the floating gate.

14. The integrated circuit according to claim 11, wherein the selection transistor comprises a source region and a drain region supported by the semiconductor substrate, wherein the source region of the selection transistor is shared with the drain region of the memory transistor.

15. A method for manufacturing a memory cell for a non-volatile memory on a semiconductor substrate, comprising:
manufacturing a memory transistor by:
forming a source region and a drain region implanted in a semiconductor substrate having an upper surface, wherein the source region is spaced from the drain region;
forming a double gate region extending in depth into the semiconductor substrate from said upper surface between the source region and the drain region and beyond a depth of the source region and the drain region; and
manufacturing a selection transistor by:
forming the selection transistor with a gate region including a first part that extends over the upper surface of the semiconductor substrate and a second part that extends over the double gate region of the memory transistor.

16. The method according to claim 15, wherein manufacturing the selection transistor further comprises forming an insulating layer between the double gate region of the memory transistor and the second part of the gate region of the selection transistor.

17. A method for manufacturing a memory cell for a non-volatile memory on a semiconductor substrate, comprising:
manufacturing a memory transistor by:
forming a source region and a drain region implanted in a semiconductor substrate having an upper surface, wherein the source region is spaced from the drain region;
forming a double gate region extending on said upper surface between the source region and the drain region; and
manufacturing a selection transistor by:
forming the selection transistor with a gate region including a first part that extends over the upper surface of the semiconductor substrate and a second part that extends over the double gate region of the memory transistor.

18. The method according to claim 16, wherein manufacturing the selection transistor further comprises forming an insulating layer between the double gate region of the memory transistor and the second part of the gate region of the selection transistor.
